(19) United States
(12) Patent Application Publication
(10) Pub. No.: US 2026/0012196 A1
(43) Pub. Date: Jan. 8, 2026

(54) Encoding and decoding of audio and/or video data

(71) Applicant: ORANGE, ISSY LES MOULINEAUX (FR)

(72) Inventors: Félix Henry, Chatillon (FR); Gordon Clare, Chatillon (FR)

(21) Appl. No.: 18/992,351

(22) PCT Filed: Jul. 7, 2023
(86) PCT No.: PCT/EP2023/068806

§ 371 Date: Jan. 8, 2025

(30) Foreign Application Priority Data
Jul. 8, 2022 (FR) 2207026

(51) Int. Cl. H03M 7/30; G06N 3/0455

(52) U.S. Cl. CPC H03M 7/6011; G06N 3/0455; H03M 7/6005

(57) ABSTRACT

A method for encoding audio and/or video data performed by an encoding device configured to perform at least one step of encoding audio and/or video data using an encoding artificial neural network. The encoding method includes: encoding the data, generating a data signal containing the encoded data, encoding information representing a decoding configuration to be had by a decoding device in order to decode the encoded data, inserting the encoded information into the signal.

### FIELD OF THE INVENTION

The present invention relates in general to the field of audio and/or video data processing, and in particular to the coding and the decoding of digital images and of digital image sequences.

The coding/decoding of digital images applies in particular to images from at least one video sequence comprising:
images from one and the same camera and following one another temporally (2D coding/decoding),
images from various cameras oriented with different views (3D coding/decoding),
corresponding texture and depth components (3D coding/decoding),
etc.

The present invention applies in a similar manner to the coding/decoding of 2D or 3D images.

The invention may be applied, in particular but not exclusively, to video coding implemented in current AVC (Advanced Video Coding), HEVC (High Efficiency Video Coding) and VVC (Versatile Video Coding) video encoders, and their extensions (MVC (Multiview Video Coding), 3D-AVC, MV-HEVC, 3D-HEVC, etc.), and to the corresponding decoding.

### PRIOR ART

At present, artificial intelligence approaches, in particular neural ones, are tending to become more common for the compression of still image, video or audio data, and many studies have reported spectacular results on their ability to represent a compressed data signal efficiently.

For example, in the context of image processing, such neural approaches are now capable of handling image compression, no longer just as a method aimed at replacing or improving a step of the classical compression approach (such as prediction or filtering), but by completely replacing the encoder and decoder, in particular using “auto-encoders”. Such an auto-encoder is for example described in the document: Theo Ladune, Pierrick Philippe, “AIC ARTIFICIAL INTELLIGENCE BASED VIDEO CODEC”, Feb. 17, 2022. Such an auto-encoder comprises an encoding neural network, which takes the images of the video at input and supplies, at output, latent variables that represent the signal representative of these compressed images. These latent variables are then quantized and then coded by entropy coding, for example by Huffman coding or CABAC (context-adaptive binary arithmetic coding) coding, so as to produce the signal representative of these compressed images.

This signal is then transmitted to a decoder, which carries out entropy decoding, then dequantization of the data of this signal, the entropy decoding and the dequantization corresponding respectively to the entropy coding and to the quantization implemented in the auto-encoder. At the end of this decoding, decoded latent variables are produced. These decoded latent variables are then supplied to a decoding neural network corresponding to the encoding neural network, the decoding neural network supplying the decoded images of the video at output.

It is also known that, in conventional video encoders, for example VVC encoders, there are various tasks for encoding an image or an image sequence, one task being associated with various constraints at the encoder, in particular in terms of coding tools used, computing power, data storage, image resolution, etc. To this end, the encoder transmits, to the decoder, information representative of these constraints in the form of syntax elements. A VVC decoder will be configured to know how to interpret such syntax elements, and will therefore be able to decode the signal received from the encoder. A decoder not compliant with VVC will not know how to interpret such syntax elements, and will therefore not be able to code the signal received from the decoder.

Given that encoding neural networks operate in a completely different way from conventional video encoders, and therefore meet different constraints, the syntax elements that are conventionally used, in particular in the VVC standard, are not suitable for these encoding neural networks. For example, some VCC syntax elements are defined over ranges of values that are limited, whereas encoding neural networks require encoding indications of a broader nature.

### AIM AND SUMMARY OF THE INVENTION

One of the aims of the invention is to address drawbacks of the abovementioned prior art by proposing:
an audio and/or video encoder based on an artificial intelligence approach that is configured to transmit, in the compressed audio and/or video signal, one or more indications of decoding features that an audio and/or video decoder has to support in order to decode the compressed video signal,
an audio and/or video decoder configured to receive this compressed audio and/or video signal and read these one or more indications of decoding features, so as to identify, in a very simple way, whether or not it is capable of decoding the compressed audio and/or video signal.

The invention thus advantageously allows an audio or video decoder, whether it is standardized (of AVC, HEVC, VVC, AAC, MPEG-H 3D Audio, etc. type) or implements decoding based on artificial intelligence, to be compatible, in read mode, with the information read from the coded audio and/or video data signal, even if the audio and/or video data have been encoded using an encoder based on an artificial intelligence approach.

To this end, one subject of the present invention relates to a method for coding audio and/or video data, implemented by a coding device configured to implement at least one step of coding the audio and/or video data using a coding artificial neural network, said coding method comprising the following:
coding the audio and/or video data,
generating a data signal that contains the coded audio and/or video data,
coding information representative of a decoding configuration that a decoding device has to have in order to decode said coded data,
inserting the coded information into the data signal.

The invention advantageously allows an audio and/or video encoder in which at least one coding step is implemented using a coding artificial neural network, and therefore requiring one or more configuration elements dedicated to implementing this particular coding step, to code information representative of these one or more corresponding coding and therefore decoding configuration elements, with a view to transmitting this information to an audio and/or video data decoder so as to inform it of the decoding capabilities that this decoder has to have in order to be able to decode the audio and/or video data.

Another subject of the present invention is a method for decoding coded audio and/or video data, implemented by a decoding device, comprising the following:
receiving a coded audio and/or video data signal,
decoding, from the signal, information representative of a decoding configuration in which at least one step of decoding the audio and/or video data is implemented using a decoding artificial neural network,
checking whether the decoding device has the decoding configuration corresponding to the decoded information,
decoding or not decoding the signal, depending on the result of the check.

The invention advantageously allows an audio and/or video decoder to identify, in the coded audio and/or video data signal that it receives, the one or more items of information relating to the decoding configuration that it has to have in order to decode the signal.

According to one particular embodiment of the abovementioned coding or decoding method, the decoding configuration belongs to:
a first category corresponding to at least one particular physical feature of hardware or software to be supported by the decoding device in order to be able to decode the signal, and/or
a second category corresponding to a particular feature of said signal, and/or
a third category corresponding to at least one particular processing functionality to be applied by the decoding device in order to be able to decode the signal.

Such an embodiment advantageously makes it possible, if a large variety of coding/decoding configurations is used, to group these configurations together by category so as to reduce the amount of information to be coded. According to one particular embodiment of the abovementioned coding or decoding method, the information representative of a decoding configuration, which is respectively coded or decoded, is associated with at least one category among the first, second or third category.

Such an embodiment advantageously makes it possible to code/decode information representative of decoding configurations of various types in a structured manner. Moreover, when there are multiple items of information representative of a decoding configuration, associated with various decoding parameters or features of one and the same category, such an embodiment makes it possible to generate more compact signaling of this information, since a single syntax element or indicator is signaled for an entire category of decoding parameters or features, rather than each decoding parameter or feature being indicated individually in the signal.

According to one particular embodiment of the abovementioned coding or decoding method, the decoding configuration belongs to a set comprising:
a maximum size of a data storage memory;
a minimum number of operations per second;
a minimum latent variable rate;
a particular type of electronic circuit;
a level of precision of mathematical representation of at least one operating parameter of the decoding artificial neural network;
the activation or non-activation of at least one reference decoding step;
at least one particular mathematical operator or a list of particular mathematical operators;
a particular mathematical function;
a number of entropy decoding statistical sources.

According to one particular embodiment of the abovementioned coding or decoding method, the information representative of a decoding configuration is contained in a set of predefined video parameters of the coding or decoding method, respectively, or, when the video data are representative of an image sequence, in a set of parameters associated with said sequence.

Such an embodiment advantageously makes it possible to use the coding syntax of existing or standardized encoders to code the information representative of a configuration element. In the case for example of an AVC, HEVC or VVC encoder, the set of predefined video parameters of the coding method is for example the VPS (Video Parameter Set) and the set of parameters associated with said sequence is the SPS (Sequence Parameter Set). In another example, the information representative of a decoding configuration is associated with a sub-image, in particular a tile or a slice as defined for example in the HEVC standard.

According to one particular embodiment of the abovementioned coding or decoding method, the information representative of a decoding configuration comprises:
a first value that is associated with a first configuration element of said decoding configuration, and
a second value that is associated with the first configuration element and with a second configuration element of said decoding configuration.

Such an embodiment advantageously makes it possible, when the configuration comprises multiple configuration elements corresponding to various decoding capabilities to be supported by the decoding device, to indicate these by nesting in the signal transmitted to the decoder.

The various abovementioned embodiments or implementation features may be added, independently or in combination with one another, to the coding or decoding method defined above.

Another subject of the present invention is an audio and/or video data signal, said signal comprising:
audio and/or video data that have been coded by a coding device configured to implement at least one step of coding the audio and/or video data using a coding artificial neural network,
coded information that is representative of a decoding configuration that a decoding device has to have in order to decode said coded audio and/or video data.

Another subject of the present invention is a device for coding audio and/or video data, configured to implement at least one step of coding the audio and/or video data using a coding artificial neural network, said coding device being configured to implement the following:
coding the audio and/or video data,
generating a data signal that contains the coded audio and/or video data,
coding information representative of a decoding configuration that a decoding device has to have in order to decode said coded data,
inserting said coded information into said data signal.

Such a coding device is in particular able to implement the abovementioned coding method.

Another subject of the present invention is a device for decoding coded audio and/or video data, configured to implement the following:
receiving a coded audio and/or video data signal,
decoding, from said signal, information representative of a decoding configuration in which at least one step of decoding the audio and/or video data is implemented using a decoding artificial neural network,
checking whether the decoding device has the decoding configuration corresponding to the decoded information,
decoding or not decoding said signal, depending on the result of the check.

Such a decoding device is in particular able to implement the abovementioned decoding method.

The invention also relates to a computer program comprising instructions for implementing the coding or decoding method according to the invention, according to any one of the particular embodiments described above, when said program is executed by a processor.

Such instructions may be stored permanently in a non-transient memory medium of the coding device implementing the abovementioned coding method or of the decoding device implementing the abovementioned decoding method.

This program may use any programming language, and be in the form of source code, object code, or intermediate code between source code and object code, such as in a partially compiled form, or in any other desirable form.

The invention also targets a computer-readable recording medium or information medium comprising instructions of a computer program as mentioned above.

The recording medium may be any entity or device capable of storing the program.

For example, the medium may comprise a storage means, such as a ROM, for example a CD-ROM, a DVD-ROM, a synthetic DNA (deoxyribonucleic acid), etc., or a microelectronic circuit ROM, or else a magnetic recording means, for example a USB key or a hard disk.

Moreover, the recording medium may be a transmissible medium such as an electrical or optical signal, which may be conveyed via an electrical or optical cable, by radio or by other means. The program according to the invention may in particular be downloaded over the Internet.

As an alternative, the recording medium may be an integrated circuit in which the program is incorporated, the circuit being adapted to execute or to be used in the execution of the coding or decoding method according to the invention.

### BRIEF DESCRIPTION OF THE DRAWINGS

Other features and advantages will become apparent on reading particular embodiments of the invention, which are given by way of illustrative and non-limiting example, and the appended drawings, in which:

FIG. 1 shows the main steps of a method for coding audio and/or video data, in one particular embodiment of the invention,

FIG. 2A shows a mode of transport of the data coded in accordance with the coding method of [FIG. 1], in one particular embodiment of the invention,

FIG. 2B shows a mode of transport of the data coded in accordance with the coding method of [FIG. 1], in another particular embodiment of the invention,

FIG. 3 shows a coding device implementing the coding method of FIG. 1, in one particular embodiment of the invention,

FIG. 4 shows the main steps of a method for decoding audio and/or video data, in one particular embodiment of the invention,

FIG. 5 shows a decoding device implementing the decoding method of FIG. 4, in one particular embodiment of the invention.

### DETAILED DESCRIPTION OF VARIOUS EMBODIMENTS OF THE INVENTION

Coding of Audio and/or Video Data

A description is given below of a method for coding audio and/or video data representative of a 2D or 3D image or image sequence. Such a coding method is able to be implemented in any type of video encoder or decoder, for example in accordance with the JPEG, AVC, HEVC, VVC standard and their extensions (MVC, 3D-AVC, MV-HEVC, 3D-HEVC, etc.) or the like, for example video encoders based on neural networks. Such a coding method is also able to be implemented in any type of audio encoder or decoder, for example in accordance with the MP3, AAC (Advanced Audio Coding), MPEG-H 3D Audio standard or the like, for example audio encoders based on neural networks.

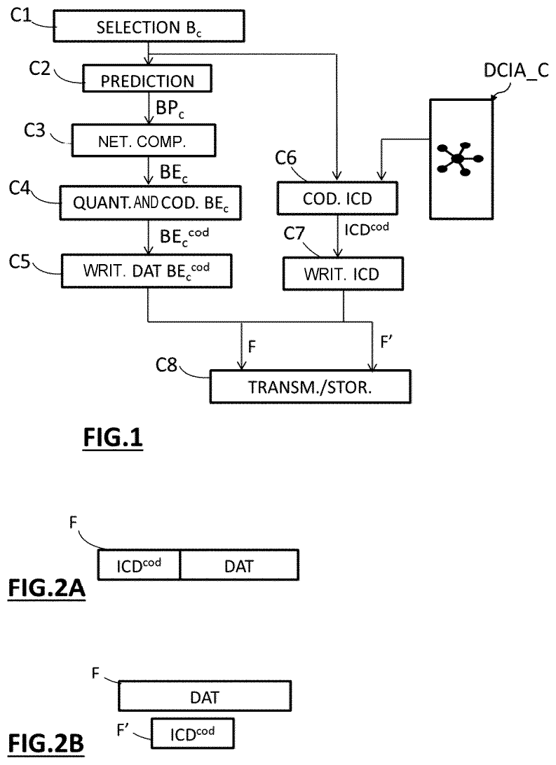

With reference to FIG. 1, the coding method according to the invention comprises the following:

In C1, current audio and/or video data are selected.

Such audio data are in the form of a current set of samples B_{c}, which may be:
a one-dimensional temporal audio signal;
a part of such a signal;
a multidimensional temporal audio signal (stereo or dimension higher than two).

Such video data are in the form of a current set of pixels B_{c}, which may be:
an original current image;
a part or a region of the original current image;
a block of the current image resulting from partitioning of this image in line with what is carried out in standardized AVC, HEVC or VVC encoders.

In C2, a current prediction dataset BP_{c}, the data being pixels for example, is computed by way of an Intra, Inter, IBC (Intra Block Copy), SKIP, etc. prediction, well known to those skilled in the art.

In the context of audio coding, the data in the current prediction dataset BP_{c} are samples.

In C3, a signal BE_{c} representative of the difference between the current set of pixels B_{c} and the current prediction set of pixels BP_{c} obtained in C2 is computed. In C4, in the case where this signal BE_{c} is the one that optimizes the coding with respect to a conventional coding performance criterion, such as for example minimizing the distortion/rate cost or else the choice of the best efficiency/complexity compromise, which are criteria that are well known to those skilled in the art, the signal BE_{c} is quantized and coded.

At the end of this operation, a quantized and entropy-coded difference signal BE_{c}^{cod} is obtained. Such entropy coding is for example carried out by Huffman coding or CABAC coding. In the preferred embodiment, the entropy coding is CABAC coding.

In C5, a signal or flow F is generated so as to contain data DAT of the quantized and coded difference signal BE_{c}^{cod}. In a manner known per se, the signal F is able to be transmitted to a decoding device or decoder, which will be described later in the description.

According to the invention, at least one of the operations C1 to C5 is implemented using a computing device based on artificial intelligence, referenced DCIA_C, which is configured to automate said at least one coding operation so as to make it more efficient and more adaptive. Such a computing device comprises for example a neural network or multiple neural networks, a support vector machine, a reasoning engine, an expert system, a fuzzy logic system, etc.

In the preferred embodiment, the computing device is a coding artificial neural network, such as for example a convolutional neural network (CNN), a multilayer perceptron, an LSTM (Long Short Term Memory), etc. Such a neural network is defined by a structure comprising for example a plurality of layers of artificial neurons and/or by a set of weights associated respectively with the artificial neurons of this network.

More particularly, in the preferred embodiment, the neural network that is used is a convolutional neural network. In one particular embodiment, the latter computes, in C3, the difference signal BE_{c} or codes the current set of pixels B_{c} together with the prediction set of pixels BP_{c} generated in C2, thus carrying out operations C3 and C4. Such a neural network is for example of the type described in the document: Ladune “Optical Flow and Mode Selection for Learning-based Video Coding”, IEEE MMSP 2020. In another particular embodiment, the prediction operation C2 is also implemented using a convolutional neural network and not using a classical prediction device, for example of VVC or CELP (Code-Excited Linear Prediction) type in the case of audio samples. Such a neural network is described in particular in the document Theo Ladune, Pierrick Philippe, “AIC ARTIFICIAL INTELLIGENCE BASED VIDEO CODEC”, Feb. 17, 2022.

The use of one or more computing devices based on artificial intelligence to implement a method for coding audio and/or video data requires the coding device that implements the coding method to have a specific hardware or software configuration. Such a configuration is correspondingly required in a decoding device, so that the latter is capable of decoding in real time the coded audio and/or video data signal received from the coding device comprising these one or more computing devices. This decoding configuration belongs to one or more categories comprising, for example:
a first category corresponding to at least one particular physical feature of hardware or software to be supported by the decoding device in order to be able to decode the signal F, and/or
a second category corresponding to one or more particular features of the data signal F, when at least one coding step is implemented by the computing device DCIA_C,
a third category corresponding to at least one particular processing functionality to be applied by the decoding device in order to be able to decode the signal F.

By way of non-exhaustive example, the first category of decoding features comprises:
an electronic circuit of a specific type used by the computing device, for example a GPU (Graphics Processing Unit), a TPU (Tensor Processing Unit), a DSP (Digital Signal Processor), or any other type of suitable electronic circuit;
a data memory size, for example a buffer memory, which the decoding device has to have in order to store all of the data required for neural decoding of the signal F;
a minimum number of operations per second, for example the TOPS (Tera Operations Per Second) that the decoding device has to be capable of implementing;
a level of precision of representation of the parameters of the computing device DCIA_C that the decoding device has to comply with in order to be able to decode the signal F, such parameters comprising for example the weights of the one and/or more decoding artificial neural networks used by the decoding device, the parameters of the activation functions applied at the output of the artificial neurons, etc.;
a number of latent variable entropy decoding sources that the decoding device has to support in order to be able to decode the signal F,
etc.

By way of non-exhaustive example, the second category of decoding features comprises:
a minimum number of latent variables to be processed per unit of time by the decoding device, when one or more neural networks are used, so that the decoding device maintains its real-time decoding capabilities;
a maximum number of latent variables per unit of time, allowing the decoding device to check whether it has the capability to decode this signal;
a minimum number of bits representative of syntax elements aimed at reconstructing latent variables per unit of time (entropy rate), so that the decoding device maintains its real-time decoding capabilities;
a maximum number of bits representative of syntax elements aimed at reconstructing latent variables per unit of time (entropy rate), so that the decoding device is able to check whether it has the capability to decode this signal;
etc.

The decoding features are transmitted to the decoding device by way of indicators that explicitly give the values of these features, or by way of more global indicators that indicate the values of multiple features in one go, using predetermined association tables, such as for example table T10 or table T11 described below.

The benefit of transmitting a latent variable rate (expressed as a number of latent variables per unit of time or as a coded rate of these latent variables per unit of time) is that of making it possible to adjust the complexity of the data requiring neural network processing with the capabilities of the decoding device to carry out neural network processing. Indeed, a coded signal representative for example of an image or of a video may contain both coded data the decoding of which implements conventional processing operations, typically carried out using a CPU (Central Processing Unit) processor, and data the decoding of which implements neural processing operations, typically carried out using a specific processor that makes it possible to carry out a very large number of small calculations of the same nature in parallel (GPU or TPU processor). Specifying the features of the latent variable rate facilitates the adjustment of the sub-portion of the signal that relates to neural data processing and the GPU or TPU capabilities of the decoding device.

By way of non-exhaustive example, the third category of decoding features comprises:
a set of predefined and standardized logical and/or mathematical operators and/or a list of logical and/or mathematical operators to be supported by the decoding device in order to be able to decode the signal;
a list of activation functions to be applied by the decoding device at the output of the one and/or more neural networks in order to be able to decode the signal;
a capability to reproduce the results of the decoding in a manner faithful to a reference (inter-platform reproducibility) that the decoding device has to have in order to be able to decode the signal;
etc.

All of these decoding features are considered both in the context of coding/decoding audio data and in the context of coding/decoding video data.

According to the invention, the coding method comprises a step C6 of coding one or more items of information ICD representative of a decoding configuration that the decoding device has to have in order to decode said coded data DAT, such a decoding configuration belonging to the abovementioned first and/or second and/or third category.

At the end of the coding C6, one or more items of information ICD^{cod} are obtained. The one or more items of information ICD^{cod} are then written, in C7, either to the data signal F or to a signal F′ associated with the signal F.

With reference to FIG. 2A, the one or more items of information ICD^{cod} are written, in C7, to the signal F, to a data packet that is able to be identified and decoded independently with respect to the coded audio and/or video data DAT, said packet comprising other information necessary for decoding the coded data DAT, such as predefined audio and/or video parameters of the coding method or, when the coded data DAT are representative of an image sequence, parameters associated with this image sequence, in a manner similar to the VPS or SPS syntax, respectively, as implemented for example in the VVC standard. According to another example, the one or more items of information ICD^{cod} are parameters associated with a sub-image, in particular a tile or a slice as defined for example in the HEVC standard.

With reference to FIG. 2B, the one or more items of information ICD^{cod} are written, in C7, to an optional packet F′ that does not need to be decoded in order to decode the data DAT, in a manner similar to writing information to an SEI (Supplemental Enhancement Information) message in accordance for example with the VVC standard.

In C8, the signal F containing the coded data DAT and the one or more coded items of information ICD^{cod}, alternatively the signal F containing the coded data DAT and the message F′ containing the one or more coded items of information ICD^{cod}, are stored or transmitted to a decoding device that will be described later in the description.

In one preferred embodiment, each decoding configuration or feature represented by an item of information ICD^{cod} is signaled individually.

Various examples of coding information ICD^{cod} are shown below in corresponding syntax tables.

With regard to particular hardware, such as for example an electronic circuit or processor of a specific type, to be supported by the decoding device, an indicator proc_idc as shown in syntax table T1 below, for example, takes eight values ranging from 0 to 7 to indicate to the decoding device the type of processor to be supported for decoding the signal F.

T1

| | Type of processor |
|---|---|
| Value of proc_idc | required for decoding |
| 0 | Irrelevant |
| 1 | CPU, GPU, DSP |
| 2 | CPU or GPU |
| 3 | CPU or DSP |
| 4 | GPU or DSP |
| 5 | GPU |
| 6 | CPU |
| 7 | DSP |

With regard to the size of the data memory that the decoding device has to have, an indicator buffer_size_idc specifies the size of this memory in bytes, or alternatively may take a predetermined number of values that are associated with predefined size limits, as in following syntax table T2. For example, the indicator buffer_size_idc takes eight values ranging from 0 to 7.

T2

| Value of | Memory size |
|---|---|
| buffer_size_idc | required |
| 0 | At least 6 GB |
| 1 | At least 8 GB |
| 2 | At least 10 GB |
| 3 | At least 12 GB |
| 4 | At least 24 GB |
| 5 | At least 36 GB |
| 6 | At least 72 GB |
| 7 | Irrelevant |

With regard to the minimum number of operations per second to be supported by the decoding device, an indicator ops_idc specifies the number of operations per second, or alternatively may take a predetermined number of values that are associated with predefined limits, as in following syntax table T3, in which the indicator ops_idc takes for example four values 0 to 3:

T3

| Value of | Number of operations |
|---|---|
| ops_idc | per second required |
| 0 | At least 1 TOPS |
| 1 | At least 5 TOPS |
| 2 | At least 20 TOPS |
| 3 | Irrelevant |

With regard to the minimum number of latent variables to be processed per unit of time by the decoding device, an indicator latent_rate_idc specifies this number as a number of variables per second, that is to say in terms of rate, or alternatively may take a predetermined number of values that are associated with predefined rate limits, as in following syntax table T4, in which the indicator latent_rate_idc takes for example seven values 0 to 6:

T4

| Value of | |
|---|---|
| latent_rate_idc | Latent variable rate required |
| 0 | At least 100000 variables per |
| | second |
| 1 | At least 500000 variables per |
| | second |
| 2 | At least 1000000 variables per |
| | second |
| 3 | At least 5000000 variables per |
| | second |
| 4 | At least 10000000 variables per |
| | second |
| 5 | At least 50000000 variables per |
| | second |
| 6 | Irrelevant |

With regard to the level of precision of representation of the parameters of the computing device DCIA_C, and in the case where this device is a neural network, an indicator precision_idc specifies the required precision of the weights of this network using the following predetermined association table T5, in which the indicator precision_idc for example takes eight values 0 to 7:

T5

| Value of | Precision of the decoding |
|---|---|
| precision_idc | network weights |
| 0 | Integers on 8 bits |
| 1 | Integers on 16 bits |
| 2 | Integers on 32 bits |
| 3 | Integers on 64 bits |
| 4 | Floating on 16 bits |
| 5 | Floating on 32 bits |
| 6 | Floating on 64 bits |
| 7 | Irrelevant |

With regard to the ability to reproduce the results of the decoding in a manner faithful to a reference (inter-platform reproducibility) that the decoding device has to have, in table T6 below, an indicator repro_flag is set:
either to a first value, for example 0, to indicate that it is not necessary for the decoding device to identically reproduce a reference decoding,
or to a second value, for example 1, to indicate that it is necessary for the decoding device to identically reproduce a reference decoding.

T6

| Value of | Identical reference |
|---|---|
| repro_flag | decoding |
| 0 | No |
| 1 | Yes |

With regard to the number of latent variable entropy decoding sources that the decoding device has to support, an indicator sources_idc specifies the number of sources, or alternatively may take a predetermined number of values that are associated with predefined limits of numbers of sources, as in following table T7, where the indicator sources_idc takes for example four values 0 to 3:

T7

| Value of | Number of entropy coding |
|---|---|
| sources_idc | sources required |
| 0 | At most 10 |
| 1 | At most 100 |
| 2 | At most 1000 |
| 3 | Irrelevant |

With regard to the set or list of predefined and standardized logical and/or mathematical operators to be supported by the decoding device, an indicator operators_idc specifies the logical and/or mathematical operators to be supported on the decoder side. According to one preferred embodiment shown in following syntax table T8, the indicator operators_idc comprises five values 0 to 4, the values 0 to 3 being constructed in a nested manner such that:
the value 0 is associated with a set of basic mathematical operators “+, −, x, /”,
the value 1 is associated with the set of basic mathematical operators “+, −, x, /” and with the set of mathematical operators “x^{y}, exp( ), sqrt( )”,
the value 2 is associated with the set of basic mathematical operators “+, −, x, /”, with the set of mathematical operators “x^{y}, exp( ), sqrt( )”, and with the operator “N!”, where N is a natural number,
the value 3 is associated with the set of basic mathematical operators “+, −, x, /”, with the set of mathematical operators “x^{y}, exp( ), sqrt( )”, with the operator “N!”, and with the set of mathematical operators “sin( ), cos( ), tan( )”.

T8

| Value of | |
|---|---|
| operators_idc | List of operators to be supported |
| 0 | +, −, ×, / |
| 1 | The above and x^{y}, exp(), sqrt() |
| 2 | The above and N!, |
| 3 | The above and sin(), cos(), tan() |
| 4 | Irrelevant |

Of course, this way of signaling the operators is not exhaustive. In other embodiments, each operator or a list of operators may be signaled individually, thereby generating a higher signaling cost.

With regard to the list of activation functions to be applied by the decoding device, an indicator activations_idc specifies the activation functions to be supported by the decoding device. According to one preferred embodiment shown in following syntax table T9, the indicator activations_idc comprises three values 0 to 2, the values 0 and 1 being constructed in a nested manner such that:
the value 0 is associated with the following list of activation functions:

$$F ( x ) = x ,$$

G(x)=0 if x<0, 1 otherwise
H(x)=0 if x<0, x otherwise
the value 1 is associated with this list of activation functions and also with the following list of activation functions:

$$I ( x ) = 1 / ( 1 + exp ( - x ) )$$

$$J ( x ) = {tan}^{- 1} ( x )$$

T9

| Value of | List of activation functions |
|---|---|
| activations_idc | to be supported |
| 0 | F(x) = x, |
| | G(x) = 0 if x < 0, 1 otherwise |
| | H(x) = 0 if x < 0, x otherwise |
| 1 | Above functions and |
| | I(x) = 1/(1 + exp(−x)) |
| | J(x) = tan⁻¹(x) |
| 2 | Irrelevant |

In one particular embodiment, a single indicator level_idc simultaneously specifies multiple decoding features to be supported by the decoding device. To this end, a correspondence table, referenced T10 below, which is predefined on both the coding device and decoding device side, is generated. Table T10 maps at least one particular value of the indicator level_idc to a particular latent variable rate, a particular data memory size, etc. In the example shown, the indicator level_idc has six values 0 to 5.

T10

| | | | | Required |
|---|---|---|---|---|
| | | | Number of | precision of |
| | | Memory | operations | the decoding |
| Value of | Latent variable | size | per second | network |
| level_idc | rate required | required | required | weights |
| 0 | At least 100000 | At least 6 GB | At least 1 | Integer on 8 |
| | variables per | | TOPS | bits |
| | second | | | |
| 1 | At least 500000 | At least 8 GB | At least 2 | Integers on |
| | variables per | | TOPS | 16 bits |
| | second | | | |
| 2 | At least 1000000 | At least 10 GB | At least 4 | Floating on |
| | variables per | | TOPS | 16 bits |
| | second | | | |
| 3 | At least 5000000 | At least 12 GB | At least 8 | Floating on |
| | variables per | | TOPS | 32 bits |
| | second | | | |
| 4 | At least | At least 24 GB | At least 16 | Floating on |
| | 10000000 | | TOPS | 64 bits |
| | variables per | | | |
| | second | | | |
| 5 | Irrelevant | Irrelevant | Irrelevant | Irrelevant |

In one particular embodiment, a series of indicators, cat1_level_idc, cat2_level_idc, cat3_level_idc, instead of a single indicator level_idc, specifies one or more decoding features depending on the first, second or third category to which these one or more decoding features belong.

To this end, a correspondence table, which is predefined on both the coding device and decoding device side, is generated for each indicator cat1_level_idc, cat2_level_idc, cat3_level_idc. Such a table is shown below and bears the reference T11.

With regard to the first category, table T11 below maps at least one particular value of the indicator cat1_level_idc to a particular type of processor, a particular data memory size, etc. In the example shown, the indicator cat1_level_idc has six values 0 to 5.

T11

| | | | | Required |
|---|---|---|---|---|
| | Type of | | Number of | precision of the |
| Value of | processor | Memory size | operations per | decoding network |
| cat1_level_idc | required | required | second required | weights |
| 0 | CPU | At least 6 GB | At least 1 TOPS | Integer on 8 bits |
| 1 | CPU | At least 8 GB | At least 2 TOPS | Integers on 16 |
| | | | | bits |
| 2 | GPU | At least 10 GB | At least 4 TOPS | Floating on 16 |
| | | | | bits |
| 3 | GPU | At least 12 GB | At least 8 TOPS | Floating on 32 |
| | | | | bits |
| 4 | TPU | At least 24 GB | At least 16 TOPS | Floating on 64 |
| | | | | bits |
| 5 | Irrelevant | Irrelevant | Irrelevant | Irrelevant |

With regard to the second category, table T12 below maps at least one particular value of the indicator cat2_level_idc to a particular latent variable rate. In the example shown, the indicator cat2_level_idc has five values 0 to 4.

T12

| Value of | Latent variable rate |
|---|---|
| cat2_level_idc | required |
| 0 | At least 100000 |
| | variables per second |
| 1 | At least 500000 |
| | variables per second |
| 2 | At least 1000000 |
| | variables per second |
| 3 | At least 5000000 |
| | variables per second |
| 4 | Irrelevant |

With regard to the third category, table T13 below maps at least one particular value of the indicator cat3_level_idc to an ability or inability to reproduce decoding results, a list of particular mathematical operators, etc. In the example shown, the indicator cat3_level_idc has four values 0 to 3.

T13

| Value of | Reproduction | List of operators to | List of activation functions |
|---|---|---|---|
| cat3_level_idc | capability | be supported | to be supported |
| 0 | No | +, −, ×, / | F(x) = x, |
| | | | G(x) = 0 if x < 0, 1 otherwise |
| | | | H(x) = 0 if x < 0, x otherwise |
| 1 | Yes | The above and x^{y}, | The above and |
| | | exp(), sqrt() | I(x) = 1/(1 + exp(−x)) |
| | | | J(x) = tan⁻¹(x) |
| 2 | Yes | The above and N! | Irrelevant |
| 3 | Irrelevant | Irrelevant | Irrelevant |

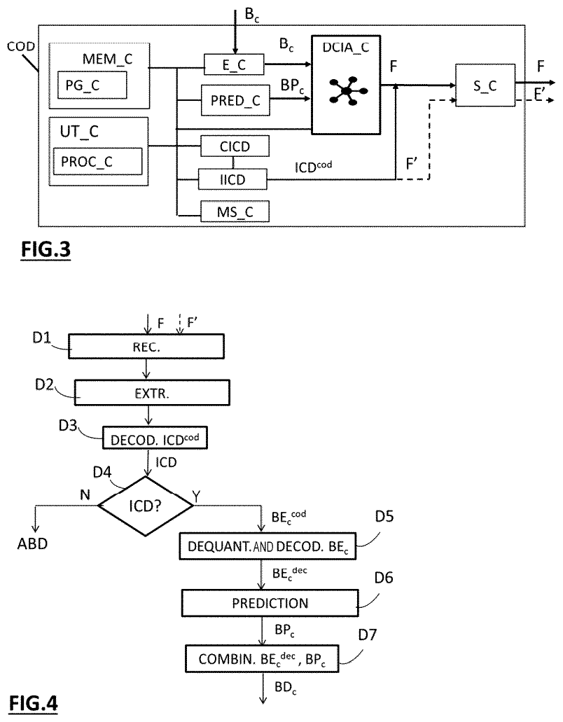

A description will now be given, with reference to FIG. 3, of an encoder COD shown in schematic form, the encoder COD being designed to implement the coding method illustrated in FIG. 1, in one particular embodiment of the invention.

According to this particular embodiment, the actions performed by the coding method are implemented by computer program instructions. To that end, the coding device COD has the conventional architecture of a computer and comprises in particular a memory MEM_C, a processing unit UT_C, equipped for example with a processor PROC_C, and driven by the computer program PG_C stored in memory MEM_C.

The computer program PG_C comprises instructions for implementing the actions of the coding method such as described above when the program is executed by the processor PROC_C.

On initialization, the code instructions of the computer program PG_C are for example loaded into a RAM memory (not shown), before being executed by the processor PROC_C. The processor PROC_C of the processing unit UT_C implements in particular the actions of the coding method described above, according to the instructions of the computer program PG_C.

The encoder COD receives, at input E_C, a current set of pixels or samples B_{c} and delivers, at output S_C, the transport flow F, which is transmitted to a decoder using a suitable communication interface (not shown).

The encoder COD comprises a prediction device PRED configured to implement the abovementioned prediction step C2. As already explained above in the description, this prediction device:
may be conventional and configured in accordance for example with the HEVC, VVC, CELP, etc. standard;
may be a neural network, for example of the type described in the abovementioned document Theo Ladune, Pierrick Philippe, “AIC ARTIFICIAL INTELLIGENCE BASED VIDEO CODEC”, Feb. 17, 2022,
etc.

The encoder COD also comprises the artificial intelligence-based computing device DCIA_C, which is for example of the type described in the abovementioned document: Ladune “Optical Flow and Mode Selection for Learning-based Video Coding”, IEEE MMSP 2020.

The encoder COD also comprises an information coding device CICD configured to implement the abovementioned step C6 of coding one or more items of information ICD representative of a decoding configuration that the decoding device has to have in order to decode the signal F.

The encoder COD also comprises a device IICD configured to implement the abovementioned step C7 of writing information ICD^{cod} obtained by the device CICD either to the data signal F or to the message F′ associated with the signal F.

The encoder COD also comprises a storage memory MS_C configured to store the syntax tables T1 to T12. As an alternative, this storage memory MS_C is not contained in the encoder COD, but is accessible thereto using any suitable means, via a communication network for example. In one embodiment, the data signal F and the optional message F′ may also be stored in the storage memory MS_C or in an additional storage memory (not shown).

Decoding of Coded Audio and/or Video Data

A description is given below of a method for decoding a coded audio and/or video data signal relating to a 2D or 3D image or image sequence. Such a decoding method is able to be implemented in any type of video decoder, for example in accordance with the JPEG, AVC, HEVC, VVC standard and their extensions (MVC, 3D-AVC, MV-HEVC, 3D-HEVC, etc.) or the like, for example video decoders based on neural networks. Such a decoding method is also able to be implemented in any type of audio decoder, for example in accordance with the MP3, AAC, MPEG-H 3D Audio standard or the like, for example audio decoders based on neural networks.

With reference to FIG. 4, the decoding method according to the invention comprises the following.

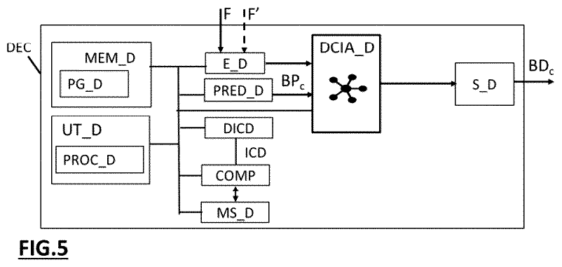

In D1, the abovementioned data signal F is received by a decoding device DEC shown in FIG. 5, said data signal containing the coded audio and/or video data DAT and the coded information ICD^{cod} representative of a particular decoding configuration that the decoding device DEC has to have in order to decode the signal F.

As an alternative, in D1, the decoding device DEC receives the following:
the data signal F containing the coded audio and/or video data DAT,
the message F′ containing the coded information ICD^{cod} representative of a particular decoding configuration that the decoding device DEC has to have in order to decode the signal F.

In D2, the coded audio and/or video data DAT and the coded information ICD^{cod} are extracted from the received data signal F.

As an alternative, in D2, the coded audio and/or video data DAT are extracted from the received data signal F and the coded information ICD^{cod} is extracted from the received message F′.

According to the invention, the one or more coded items of information ICD^{cod} are decoded in D3. At the end of this operation, the information ICD is reconstructed, thereby allowing the decoder to identify the one or more decoding features required for it to be capable of decoding the coded audio and/or video data DAT. To this end, in one particular embodiment of the invention, the value of one or more indicators, such as for example the indicators proc_idc, buffer_size_idc, ops_idc, latent_rate_idc, precision_idc, repro_flag, sources_idc, operators_idc, activations_idc, level_idc, cat1_level_idc, cat2_level_idc, cat3_level_idc, is read and then mapped to its associated decoding feature or else its associated decoding features, in the case in particular of the indicators cat1_level_idc and cat3_level_idc. Such mapping is implemented using the abovementioned correspondence tables T1 to T13, which are made accessible to the decoding device DEC.

In D4, the decoding device DEC compares the one or more decoding features identified in D3 with the one or more decoding features specific thereto, respectively.

Such a comparison is made possible by the fact that the decoding device DEC is able to access the technical features of the platform on which it operates (be this software or hardware or hybrid) and the performance that it is capable of achieving.

If, at the end of the comparison D4, the decoding device DEC does not have the one or more decoding features identified in D3, the decoding of the coded audio and/or video data DAT is not implemented. The decoding is therefore abandoned (ABD).

If, at the end of the comparison D4, the decoding device DEC has the one or more decoding features identified in D3, the decoding of the coded audio and/or video data DAT is implemented using an artificial intelligence-based computing device DCIA_D, the computing device DCIA_D implementing decoding corresponding to the coding implemented by the computing device DCIA_C.

To this end, in D5, dequantization and entropy decoding of the coded audio and/or video data DAT are carried out. Such entropy decoding is for example Huffman decoding or CABAC decoding. In the preferred embodiment, the entropy decoding is CABAC decoding. At the end of this operation, a decoded difference signal BE_{c}^{dec} is obtained.

In D6, a prediction is implemented, generating the current prediction dataset BP_{c}, these data being for example pixels here, but also possibly being samples of an audio signal.

Steps D5 and D6 may be implemented in any order or simultaneously.

In D7, a reconstructed current set of pixels BD_{c} is computed by combining the decoded difference signal BE dec obtained in D5 with the prediction set of pixels or samples BP_{c} obtained in D6.

In a manner known per se, the reconstructed current set of pixels BD_{c} may possibly undergo filtering by a loop filter performed on the reconstructed signal, which is well known to those skilled in the art.

Of course, in the case where the difference signal BE_{c} that was computed during the abovementioned coding method is zero, which may be the case for the SKIP coding mode, step D2 of extracting the difference signal BE_{c} and step D5 of dequantization and entropy decoding are not implemented.

A description will now be given, with reference to FIG. 5, of a decoder DEC shown in schematic form, the decoder DEC being designed to implement the decoding method illustrated in FIG. 4, in one particular embodiment of the invention.

According to this particular embodiment, the actions performed by the decoding method are implemented by computer program instructions. To that end, the decoding device DEC has the conventional architecture of a computer and comprises in particular a memory MEM_D, a processing unit UT_D, equipped for example with a processor PROC_D, and driven by the computer program PG_D stored in memory MEM_D. The computer program PG_D comprises instructions for implementing the actions of the decoding method such as described above when the program is executed by the processor PROC_D.

The decoder DEC receives, at input E_D, the data signal F, possibly the message F′, transmitted by the encoder COD of FIG. 3, and delivers, at output S_D, the current decoded set of pixels or samples BD_{c}.

The decoder DEC also comprises an information decoding device DICD configured to implement the abovementioned step D3 of decoding one or more coded items of information ICD^{cod} representative of a decoding configuration that the decoder DEC has to have in order to decode the signal F.

The decoder DEC also comprises a device COMP configured to compare, in D4, the reconstructed one or more items of information ICD representative of a decoding configuration that the decoder DEC has to have in order to decode the signal F with the specific decoding features of the decoder DEC.

In a manner corresponding to the encoder COD of FIG. 3, the decoder DEC also comprises a storage memory MS_D configured to store abovementioned syntax tables T1 to T13. As an alternative, this storage memory MS_D is not contained in the decoder DEC, but is accessible thereto using any suitable means, via a communication network for example. In one embodiment, the data signal F and the optional message F′ may also be stored in the storage memory MS_D or in an additional storage memory (not shown).

The decoder DEC comprises a prediction device PRED_D configured to implement the abovementioned prediction step D6. As already explained above in the description, this prediction device:
may be conventional and configured in accordance for example with the HEVC, VVC, CELP, etc. standard;
may be a neural network, for example of the type described in the abovementioned document Theo Ladune, Pierrick Philippe, “AIC ARTIFICIAL INTELLIGENCE BASED VIDEO CODEC”, Feb. 17, 2022,
etc.

The decoder DEC may also comprise an artificial intelligence-based computing device, referenced DCIA_D, which is configured to automate at least one decoding operation so as to make it more efficient and more adaptive. Such a computing device comprises for example a decoding artificial neural network or multiple decoding artificial neural networks, a support vector machine, a reasoning engine, an expert system, a fuzzy logic system, etc.

In the preferred embodiment, the computing device DCIA_D is a neural network, such as for example a convolutional neural network or CNN, a multilayer perceptron, an LSTM, etc. More particularly, in the preferred embodiment, the neural network that is used is a convolutional neural network. Such a neural network is defined by a structure comprising for example a plurality of layers of artificial neurons and/or by a set of weights associated respectively with the artificial neurons of this network.

In one particular embodiment, the neural network DCIA_D combines, in D7, the decoded difference signal BE dec obtained in D5 with the prediction set of pixels or samples BP_{c} generated in D6. Such a neural network is for example of the type described in the document: Ladune “Optical Flow and Mode Selection for Learning-based Video Coding”, IEEE MMSP 2020. In another particular embodiment, the prediction operation D6 is also implemented using a convolutional neural network and not using a classical prediction device, for example of VVC type. Such a neural network is described in particular in the document Theo Ladune, Pierrick Philippe, “AIC ARTIFICIAL INTELLIGENCE BASED VIDEO CODEC”, Feb. 17, 2022.

It goes without saying that the embodiments described above have been given purely by way of completely non-limiting indication, and that numerous modifications may be easily made by a person skilled in the art without otherwise departing from the scope of the invention.

1. A coding method comprising:
coding audio and/or video data, implemented by a coding device configured to implement at least one step of coding the audio and/or video data using a coding artificial neural network, said coding comprising:
coding the audio and/or video data,
generating a data signal that contains the coded audio and/or video data,
coding information representative of a decoding configuration relating to use of said network that a decoding device has to have in order to decode said coded data, and
inserting the coded information into the data signal.

2. A decoding method comprising:
decoding coded audio and/or video data, implemented by a decoding device, comprising:
receiving a coded audio and/or video data signal,
decoding, from said signal, information representative of a decoding configuration in which at least one step of decoding the audio and/or video data is implemented using a decoding artificial neural network,
checking whether the decoding device has the decoding configuration corresponding to the decoded information, and
decoding or not decoding said signal, depending on a result of the checking.

3. The coding method as claimed in claim 1, wherein the decoding configuration belongs to:
a first category corresponding to at least one particular physical feature of hardware or software to be supported by the decoding device in order to be able to decode the signal, and/or
a second category corresponding to a particular feature of said signal, and/or
a third category corresponding to at least one particular processing functionality to be applied by the decoding device in order to be able to decode the signal.

4. The coding method as claimed in claim 3, wherein the information representative of a decoding configuration, which is coded, is associated with at least one category among the first, second or third category.

5. The coding method as claimed in claim 1, wherein the decoding configuration belongs to a set comprising:
a maximum size of a data storage memory;
a minimum number of operations per second;
a minimum latent variable rate;
a predetermined number of values respectively associated with predefined latent variable rate limits;
a particular type of electronic circuit;
a minimum number of bits representative of syntax elements aimed at reconstructing latent variables per unit of time;
a maximum number of bits representative of syntax elements aimed at reconstructing latent variables per unit of time;
a level of precision of mathematical representation of at least one operating parameter of a decoding artificial neural network;
the activation or non-activation of at least one decoding identical to a reference decoding;
at least one particular mathematical operator or a list of particular mathematical operators;
a particular mathematical function;
a number of entropy decoding statistical sources.

6. The coding method as claimed in claim 1, wherein the information representative of a decoding configuration is contained in a set of predefined video parameters of the coding method, or, when the video data are representative of an image sequence, in a set of parameters associated with said sequence.

7. The coding method as claimed in claim 1, wherein the information representative of a decoding configuration comprises:
a first value that is associated with a first configuration element of said decoding configuration, and
a second value that is associated with the first configuration element and with a second configuration element of said decoding configuration.

8. (canceled)

9. A decoding device comprising:
at least one processor; and
at least one non-transitory computer readable medium comprising instructions stored thereon which when executed by the at least one processor configure the decoding device to decode coded audio and/or video data, by:
receiving a coded audio and/or video data signal,
decoding, from said signal, information representative of a decoding configuration in which at least one step of decoding the audio and/or video data is implemented using a decoding artificial neural network,
checking whether the decoding device has the decoding configuration corresponding to the decoded information, and
decoding or not decoding said signal, depending on the result of the checking.

10. A non-transitory computer-readable information medium comprising instructions of a computer program stored thereon which when executed by at least one processor of the coding device configure the coding device to code audio and/or video data according to the method of claim 1.

11. A non-transitory computer-readable information medium comprising instructions of a computer program stored thereon which when executed by at least one processor of the decoding device configure the decoding device to decode coded audio and/or video data according to the method of claim 2.

12. The decoding method as claimed in claim 2, wherein the decoding configuration belongs to:
a first category corresponding to at least one particular physical feature of hardware or software to be supported by the decoding device in order to be able to decode the signal, and/or
a second category corresponding to a particular feature of said signal, and/or
a third category corresponding to at least one particular processing functionality to be applied by the decoding device in order to be able to decode the signal.

13. The decoding method as claimed in claim 12, wherein the information representative of a decoding configuration, which is respectively decoded, is associated with at least one category among the first, second or third category.

14. The decoding method as claimed in claim 2, wherein the decoding configuration belongs to a set comprising:
a maximum size of a data storage memory;
a minimum number of operations per second;
a minimum latent variable rate;
a predetermined number of values respectively associated with predefined latent variable rate limits;
a particular type of electronic circuit;
a minimum number of bits representative of syntax elements aimed at reconstructing latent variables per unit of time;
a maximum number of bits representative of syntax elements aimed at reconstructing latent variables per unit of time;
a level of precision of mathematical representation of at least one operating parameter of the decoding artificial neural network;
activation or non-activation of at least one decoding identical to a reference decoding;
at least one particular mathematical operator or a list of particular mathematical operators;
a particular mathematical function;
a number of entropy decoding statistical sources.

15. The decoding method as claimed in claim 2, wherein the information representative of a decoding configuration is contained in a set of predefined video parameters of the decoding method, or, when the video data are representative of an image sequence, in a set of parameters associated with said sequence.

16. The decoding method as claimed in claim 2, wherein the information representative of a decoding configuration comprises:
a first value that is associated with a first configuration element of said decoding configuration, and
a second value that is associated with the first configuration element and with a second configuration element of said decoding configuration.
